(19) United States
(12) Patent Application Publication
(10) Pub. No.: US 2026/0076256 A1
(43) Pub. Date: Mar. 12, 2026

(54) SEMICONDUCTOR PACKAGE AND METHOD OF FABRICATING THE SAME

(71) Applicant: Taiwan Semiconductor Manufacturing Company, Ltd., Hsinchu (TW)

(72) Inventors: Sheng-An Kuo, Hsinchu (TW); Chao-Wen Shih, Hsinchu County (TW); Kuo-Chiang Ting, Hsinchu City (TW); Yen-Ming Chen, Hsin-Chu County (TW)

(73) Assignee: Taiwan Semiconductor Manufacturing Company, Ltd., Hsinchu (TW)

(21) Appl. No.: 18/829,101

(22) Filed: Sep. 9, 2024

(51) Int. Cl. H01L 25/10; H01L 23/00; H01L 23/31; H01L 23/498; H01L 25/00

(52) U.S. Cl. CPC H10W 90/00; H10W 74/111; H10W 90/701; H10W 70/60; H10W 74/15; H10W 90/22; H10W 90/724; H10W 90/734

(57) ABSTRACT

A semiconductor package includes a plurality of first semiconductor dies, a first bonding layer, a redistribution layer, a plurality of second semiconductor dies and a plurality of conductive terminals. The first bonding layer is disposed on the first semiconductor dies, and includes a plurality of first bonding pads. The redistribution layer is disposed on and electrically connected to the first bonding pads. The second semiconductor dies are disposed on and electrically connected to the redistribution layer, wherein backside surfaces of the second semiconductor dies are facing active surfaces of the first semiconductor dies. The conductive terminals are disposed on and electrically connected to the second semiconductor dies.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 10 are schematic sectional views of various stages in a method of fabricating a semiconductor package according to some exemplary embodiments of the present disclosure.

FIG. 11 is a schematic sectional view of a semiconductor package according to some exemplary embodiments of the present disclosure.

FIG. 12 is a schematic sectional view of a semiconductor package according to some other exemplary embodiments of the present disclosure.

FIG. 13 is a schematic sectional view of a semiconductor package according to some other exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor package is formed with a plurality of first semiconductor dies and a plurality of second semiconductor dies, whereby a redistribution layer is formed between the first and second semiconductor dies for improving the connection integrity. The arrangement of the redistribution layer between the first and second semiconductor dies allows for additional paths for signal communication, which can be used for super powerful data processing.

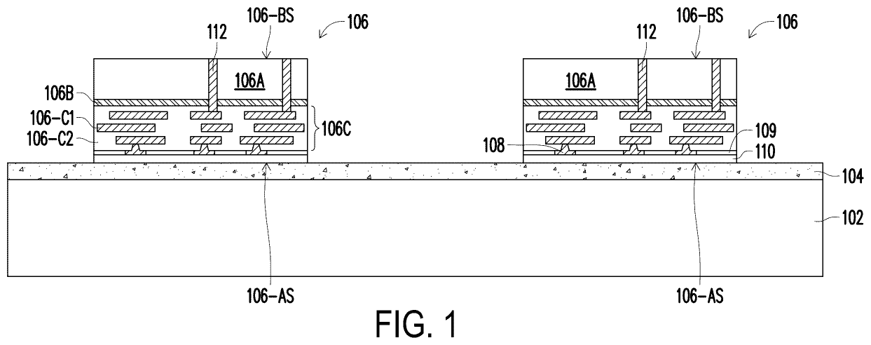

FIG. 1 to FIG. 10 are schematic sectional views of various stages in a method of fabricating a semiconductor package according to some exemplary embodiments of the present disclosure. Referring to FIG. 1, a first carrier 102 is provided. In some embodiments, the first carrier 102 may be a glass carrier or any suitable carrier for carrying a semiconductor wafer or a reconstituted wafer for the manufacturing method of the semiconductor package. In some embodiments, the first carrier 102 is coated with a debond layer 104. The material of the debond layer 104 may be any material suitable for bonding and de-bonding the first carrier 102 from the above layer(s) or any wafer(s) disposed thereon.

In some embodiments, the debond layer 104 may include a dielectric material layer made of a dielectric material including any suitable polymer-based dielectric material (such as benzocyclobutene (“BCB”), polybenzoxazole (“PBO”)). In an alternative embodiment, the debond layer 104 may include a dielectric material layer made of an epoxy-based thermal-release material, which loses its adhesive property when heated, such as a light-to-heat-conversion (LTHC) release coating film. In a further alternative embodiment, the debond layer 104 may include a dielectric material layer made of an ultra-violet (UV) glue, which loses its adhesive property when exposed to UV lights. In certain embodiments, the debond layer 104 may be dispensed as a liquid and cured, or may be a laminate film laminated onto the first carrier 102, or may be the like. The top surface of the debond layer 104, which is opposite to a bottom surface contacting the first carrier 102, may be levelled and may have a high degree of coplanarity. In certain embodiments, the debond layer 104 is, for example, a LTHC layer with good chemical resistance, and such layer enables room temperature de-bonding from the first carrier 102 by applying laser irradiation, however the disclosure is not limited thereto.

In an alternative embodiment, a buffer layer (not shown) may be coated on the debond layer 104, where the debond layer 104 is sandwiched between the buffer layer and the first carrier 102, and t he top surface of the buffer layer may further provide a high degree of coplanarity. In some embodiments, the buffer layer may be a dielectric material layer. In some embodiments, the buffer layer may be a polymer layer which made of polyimide, polybenzoxazole (PBO), benzocyclobutene (BCB), or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

Referring to FIG. 1, in a subsequent step, a plurality of semiconductor dies 106 are placed on the first carrier 102 over the debond layer 104. The semiconductor dies 106 includes an active surface 106-AS and a backside surface 106-BS, wherein the semiconductor dies 106 are placed on the first carrier 102 so that the active surface 106-AS is facing the debond layer 104, while the backside surface 106-BS is facing away from the debond layer 104. In the exemplary embodiment, each of the semiconductor dies 106 includes a semiconductor substrate 106A, a buffer layer 106B disposed on the semiconductor substrate 106A, an interconnection layer 106C (die interconnection layer) disposed on the buffer layer 106B, conductive pads 108 connected to the interconnection layer, a dielectric layer 109 surrounding the conductive pads 108, a protection layer 110 covering the conductive pads 108, and backside vias 112 extending from the interconnection layer 106C to the semiconductor substrate 106A.

In some embodiments, the semiconductor substrate 106A may be a bulk silicon substrate or a silicon-on-insulator (SOI) substrate, and further includes active components (e.g., transistors or the like) and optionally passive components (e.g., resistors, capacitors, inductors or the like) formed therein. The buffer layer 106B is formed on the semiconductor substrate 106A, and may include polyimide, polybenzoxazole (PBO), benzocyclobutene (BCB), or any other suitable dielectric material.

The interconnection layer 106C is formed on the buffer layer 106B and includes a plurality of metal lines 106C-1, a plurality of metal vias (not shown), and a plurality of dielectric layers 106C-2 that are alternately stacked. The dielectric layers 106C-2 may be formed, for example, of a low dielectric constant (low-K) dielectric material, such as phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like. Furthermore, the dielectric layers 106C-2 may be formed by any suitable methods, such as spin coating, chemical vapor deposition (CVD), and/or plasma-enhanced CVD (PECVD), combinations thereof, or the like. In some embodiment, the metal lines 106C-1 and/or vias (not shown) are formed inside the dielectric layers 106C-2 to provide an electrical connection to the electrical circuitry formed in the semiconductor substrate 106A.

The conductive pads 108 are disposed on and electrically connected to a topmost metal line 106C-1 of the interconnection layer 106C. The conductive pads 108 may be aluminum pads, copper pads or other suitable metal pads. The dielectric layer 109 is disposed on the interconnection layer 106C and surrounding the conductive pads 108. In some embodiments, the conductive pads 108 have a body portion and a via portion, whereby the body portion is laterally surrounded by the dielectric layer 109, while the via portion is physically joining the body portion to the metal line 106C-1 of the interconnection layer 106C. In certain embodiments, the protection layer 110 is disposed on the dielectric layer 109 and covering the conductive pads 108. For example, the protection layer 110 include materials such as polymers, dielectric materials, a resin material or the like. In some embodiments, the backside vias 112 are electrically connected to a bottommost metal line 106C-1 of the interconnection layer 140C, wherein the backside vias 112 are formed by electroplating or deposition of a metal material such as copper or copper alloys, or the like.

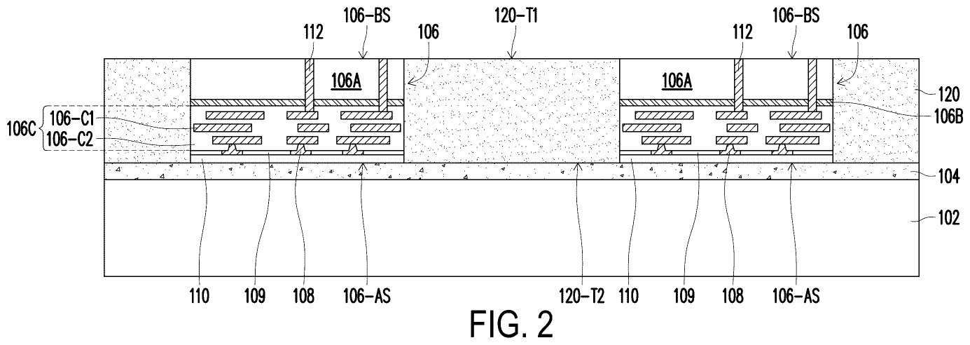

Referring to FIG. 2, after placing the plurality of semiconductor dies 106 on the first carrier 102, an insulating encapsulant 120 (or molding compound) is formed to encapsulate the semiconductor dies 106. For example, the insulating encapsulant 120 is formed to laterally surround the semiconductor dies 106. In some embodiments, the insulating encapsulant 120 is formed through, for example, a compression molding process or transfer molding. In one embodiment, a curing process is performed to cure the insulating encapsulant 120.

In some embodiments, a material of the insulating encapsulant 120 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 120 may include an acceptable insulating encapsulation material. In some embodiments, the insulating encapsulant 120 may further include inorganic filler or inorganic compound (e.g. silica, clay, and so on) which can be added therein to optimize coefficient of thermal expansion (CTE) of the insulating encapsulant 108. The disclosure is not limited thereto.

After forming the insulating encapsulant 120, portions of the insulating encapsulant 120 and portions of the backside surfaces 106-BS of the semiconductor dies 106 are removed. For example, the insulating encapsulant 120 and the backside surfaces 106-BS of the semiconductor dies 106 are ground or polished by a planarization step, such as a mechanical grinding process and/or a chemical mechanical polishing (CMP) process until the backside vias 112 are revealed. In other words, the backside vias 112 are passing through the semiconductor substrate 106 and extends to a backside surface 106-BS of the semiconductor dies 106. After the planarization step, the backside surfaces 106-BS of the semiconductor dies 106, a surface of the backside vias 112, and a surface 120-T1 of the insulating encapsulant 120 are coplanar and levelled with one another. In some embodiments, after the mechanical grinding or chemical mechanical polishing (CMP) steps, a cleaning step may be optionally performed. For example, the cleaning step is preformed to clean and remove the residue generated from the planarization step. However, the disclosure is not limited thereto, and the planarization step may be performed through any other suitable methods.

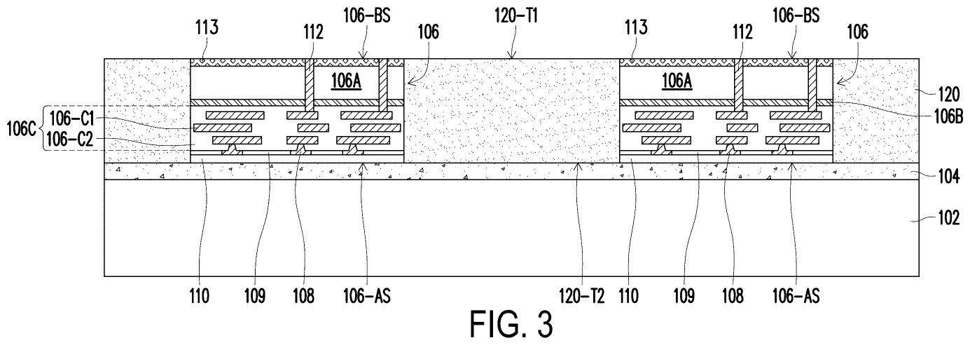

Referring to FIG. 3, in a subsequent step, the semiconductor substrate 106A of the semiconductor dies 106 may be further recessed, for example through an etching process, so that the backside vias 112 are protruding out from the semiconductor substrate 106A. In some embodiments, a passivation layer 113 is formed on the semiconductor substrate 106A and laterally surrounds the backside vias 112. For example, the passivation layer 113 is formed by depositing a dielectric layer, which may be formed of silicon oxide, silicon nitride, or the like, and performing a planarization process to remove the excess portions of the dielectric material over the backside vias 112 and over the insulating encapsulant 120, so that the backside vias 112 are revealed.

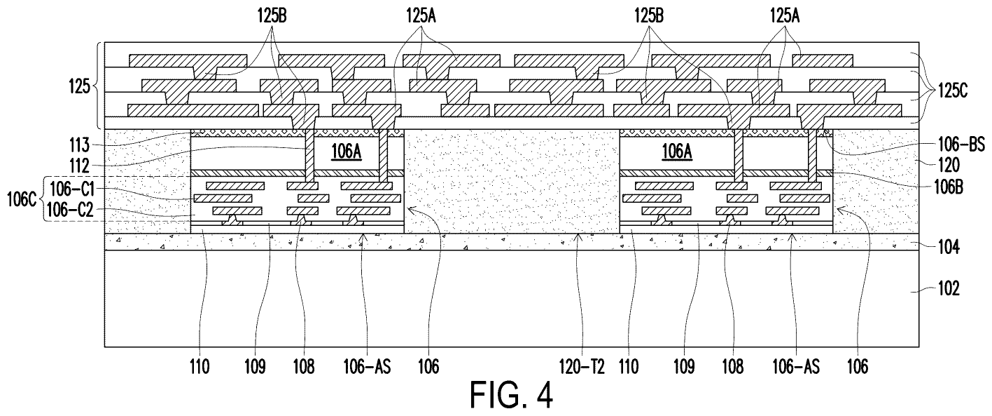

Referring to FIG. 4, after forming the passivation layer 113, a redistribution layer 125 is formed on the insulating encapsulant 120 and over the semiconductor dies 106. For example, the redistribution layer 125 is physically and electrically connected to the backside vias 112 of the semiconductor dies 106. Furthermore, the redistribution layer 125 is physically contacting and covering the passivation layer 113. In some embodiments, the formation of the redistribution layer 125 includes forming a plurality of conductive lines 125A, a plurality of conductive vias 125B and a plurality of dielectric layers 125C alternately stacked. Although only three layers of the conductive lines 125A and the conductive vias 125B, and four layers of dielectric layers 125C are illustrated herein, however, the scope of the disclose is not limited by the embodiments of the disclosure. In other embodiments, the number of conductive lines 125A, conductive vias 125B and the dielectric layers 125C may be adjusted based on product requirement. In some embodiments, the redistribution layer 125 is electrically connected to the backside vias 112 of the semiconductor dies 106 through the conductive lines 125A and the conductive vias 125B.

In some embodiments, a material of the dielectric layers 125C may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 125C may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive lines 125A and conductive vias 125B may be made of conductive materials formed by electroplating or deposition, such as aluminum, titanium, copper, nickel, tungsten, and/or alloys thereof, which may be patterned using a photolithography and etching process. In some embodiments, the conductive lines 125A and conductive vias 125B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

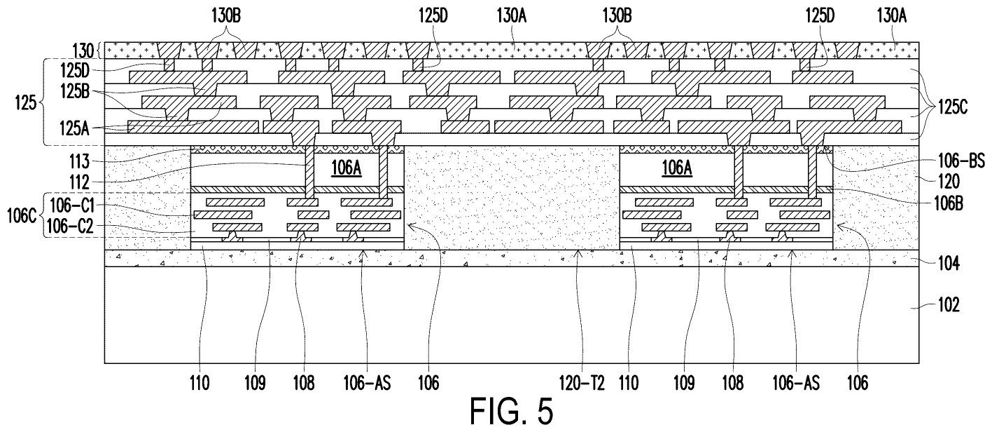

Referring to FIG. 5, in a subsequent step, the dielectric layers 125C may be further patterned to form openings revealing a topmost conductive line 125A of the redistribution layer 125. Thereafter, a plurality of connecting vias 125D are formed in the openings and electrically connected to the topmost conductive line 125A of the redistribution layer 125. In some embodiments, a material of the connecting vias 125D is similar to a material of the conductive vias 125B, thus its details will not be repeated herein. In some embodiments, the conductive vias 125B has slanted sidewalls, whereas the connecting vias 125D has linear sidewalls. For example, a lateral dimension of the conductive vias 125B increases in a buildup direction of the redistribution layer 125, while a lateral dimension of the connecting vias 125D is kept constant along the buildup direction.

After forming the connecting vias 125D, a connection layer 130 is formed on the redistribution layer 125 and electrically connected to the redistribution layer 125. For example, the connection layer 130 includes a plurality of connection pads 130B and a dielectric layer 130A surrounding the connection pads 130B. In some embodiments, the connection pads 130B are made of conductive materials formed by electroplating or deposition, and include materials such as copper, copper alloys, or other suitable metallic materials which may be patterned using a photolithography and etching process. Furthermore, the dielectric layer 130A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 130A is formed by suitable fabrication techniques such as spin-on coating, chemical vapor deposition (CVD), plasma-enhanced chemical vapor deposition (PECVD) or the like. The disclosure is not limited thereto. In the exemplary embodiment, the connection layer 130 is electrically connected to the redistribution layer 125 by physically and electrically joining the connection pads 130B to the connecting vias 125D. Furthermore, sidewalls of the connection layer 130 are aligned with sidewalls of the redistribution layer 125.

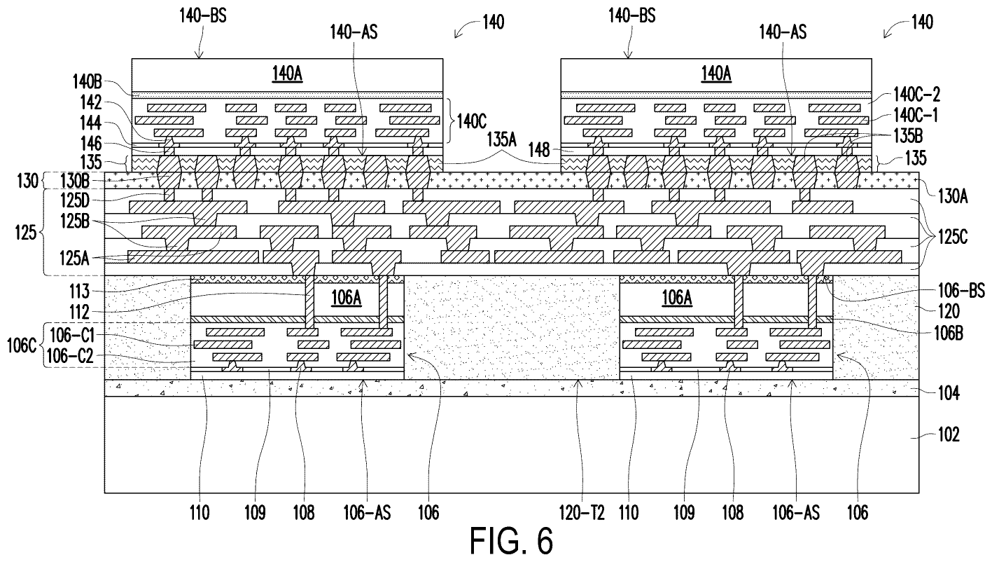

Referring to FIG. 6, after forming the connection layer 130, a plurality of semiconductor dies 140 is bonded to the connection layer 130 through a first bonding layer 135. For example, the first bonding layer 135 is first formed on an active surface 140-AS of the semiconductor dies 140 so that the first bonding layer 135 can be bonded to the connection layer 130 along with the semiconductor dies 140. In some embodiments, the semiconductor dies 140 and the first bonding layer 135 are placed over the connection layer 130 by, e.g., a pick-and-place process. In some embodiments, forming the first bonding layer 135 includes forming a plurality of bonding pads 135B disposed on and electrically connected to the semiconductor dies 140, and forming a dielectric layer 135A surrounding the bonding pads 135B. In certain embodiments, sidewalls of the first bonding layer 135 are aligned with sidewalls of the semiconductor dies 140. Furthermore, sidewalls of the first bonding layer 135 are misaligned with sidewalls of the connection layer 130.

In some embodiments, the bonding pads 135B are made of conductive materials formed by electroplating or deposition, and include materials such as copper, copper alloys, or other suitable metallic materials which may be patterned using a photolithography and etching process. Furthermore, the dielectric layer 135A may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 135A is formed by suitable fabrication techniques such as spin-on coating, chemical vapor deposition (CVD), plasma-enhanced chemical vapor deposition (PECVD) or the like. The disclosure is not limited thereto.

As illustrated in FIG. 6, the first bonding layer 135 is bonded to the connection layer 130 using dielectric-to-dielectric bonding and metal-to-metal bonding. For example, the dielectric layer 130A of the connection layer 130 is directly joined with the dielectric layer 135A of the first bonding layer 135 using dielectric-to-dielectric bonding, while the connection pads 130 of the connection layer 130 are directly joined with the bonding pads 135B of the first bonding layer 135 using metal-to-metal bonding. After bonding the semiconductor dies 140 to the connection layer 130, the first bonding layer 135 is sandwiched in between the semiconductor dies 140 and the connection layer 130.

As further illustrated in FIG. 6, the semiconductor dies 140 are bonded onto the connection layer 130 so that active surfaces 140-AS of the semiconductor dies 140 are facing the backside surfaces 106-BS of the semiconductor dies 106. In other words, the semiconductor dies 106 and the semiconductor dies 140 are arranged in a face-to-back manner. In the exemplary embodiment, each of the semiconductor dies 140 includes, a semiconductor substrate 140A, a buffer layer 140B disposed on the semiconductor substrate 140A, an interconnection layer 140C (die interconnection layer) disposed on the buffer layer 140B, conductive pads 142 connected to the interconnection layer 140C, a dielectric layer 144 surrounding the conductive pads 142, a protection layer 148 covering the conductive pads 142, and conductive posts 146 disposed on the conductive pads 142 and embedded in the protection layer 148.

In some embodiments, the semiconductor substrate 140A may be a bulk silicon substrate or a silicon-on-insulator (SOI) substrate, and further includes active components (e.g., transistors or the like) and optionally passive components (e.g., resistors, capacitors, inductors or the like) formed therein. The buffer layer 140B is formed on the semiconductor substrate 140A, and may include polyimide, polybenzoxazole (PBO), benzocyclobutene (BCB), or any other suitable dielectric material.

The interconnection layer 140C is formed on the buffer layer 140B and includes a plurality of metal lines 140C-1, a plurality of metal vias (not shown), and a plurality of dielectric layers 140C-2 that are alternately stacked. The dielectric layers 140C-2 may be formed, for example, of a low dielectric constant (low-K) dielectric material, such as phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like. Furthermore, the dielectric layers 140C-2 may be formed by any suitable methods, such as spin coating, chemical vapor deposition (CVD), and/or plasma-enhanced CVD (PECVD), combinations thereof, or the like. In some embodiment, the metal lines 140C-1 and/or vias (not shown) are formed inside the dielectric layers 140C-2 to provide an electrical connection to the electrical circuitry formed in the semiconductor substrate 140A.

The conductive pads 142 are disposed on and electrically connected to a topmost metal line 140C-1 of the interconnection layer 140C. The conductive pads 142 may be aluminum pads, copper pads or other suitable metal pads. The dielectric layer 144 is disposed on the interconnection layer 140C and surrounding the conductive pads 142. In some embodiments, the conductive pads 142 have a body portion and a via portion, whereby the body portion is laterally surrounded by the dielectric layer 144, while the via portion is physically joining the body portion to the metal line 140C-1 of the interconnection layer 140C. In certain embodiments, the protection layer 148 is disposed on the dielectric layer 144 and covering the conductive pads 142. For example, the protection layer 148 include materials such as polymers, dielectric materials, a resin material or the like. In some embodiments, the conductive posts 146 are embedded in the protection layer 148, and are physically and electrically joining the conductive pads 142 to the bonding pads 135B of the first bonding layer 135.

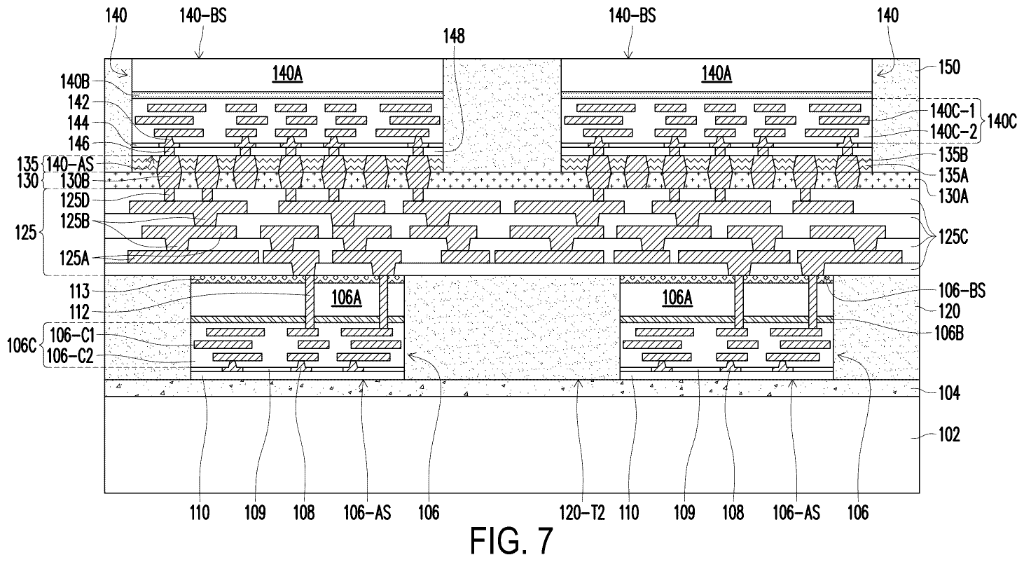

Referring to FIG. 7, in a subsequent step, an insulating encapsulant 150 (or molding compound) is formed to encapsulate the semiconductor dies 140. For example, the insulating encapsulant 150 is formed to laterally surround the semiconductor dies 140. In some embodiments, the insulating encapsulant 150 is physically separated from the insulating encapsulant 120. In some embodiments, the insulating encapsulant 150 is formed through, for example, a compression molding process or transfer molding. In one embodiment, a curing process is performed to cure the insulating encapsulant 150.

In some embodiments, a material of the insulating encapsulant 150 includes polymers (such as epoxy resins, phenolic resins, silicon-containing resins, or other suitable resins), dielectric materials having low permittivity (Dk) and low loss tangent (Df) properties, or other suitable materials. In an alternative embodiment, the insulating encapsulant 150 may include an acceptable insulating encapsulation material. In some embodiments, the insulating encapsulant 150 may further include inorganic filler or inorganic compound (e.g. silica, clay, and so on) which can be added therein to optimize coefficient of thermal expansion (CTE) of the insulating encapsulant 150. The disclosure is not limited thereto.

After forming the insulating encapsulant 150, portions of the insulating encapsulant 150 and portions of the backside surfaces 140-BS of the semiconductor dies 140 are removed. For example, the insulating encapsulant 150 and the backside surfaces 140-BS of the semiconductor dies 140 are ground or polished by a planarization step, such as a mechanical grinding process and/or a chemical mechanical polishing (CMP) process. After the planarization step, the backside surfaces 140-BS of the semiconductor dies 140 and a surface of the insulating encapsulant 150 are coplanar and levelled with one another. In some embodiments, after the mechanical grinding or chemical mechanical polishing (CMP) steps, a cleaning step may be optionally performed. For example, the cleaning step is preformed to clean and remove the residue generated from the planarization step. However, the disclosure is not limited thereto, and the planarization step may be performed through any other suitable methods.

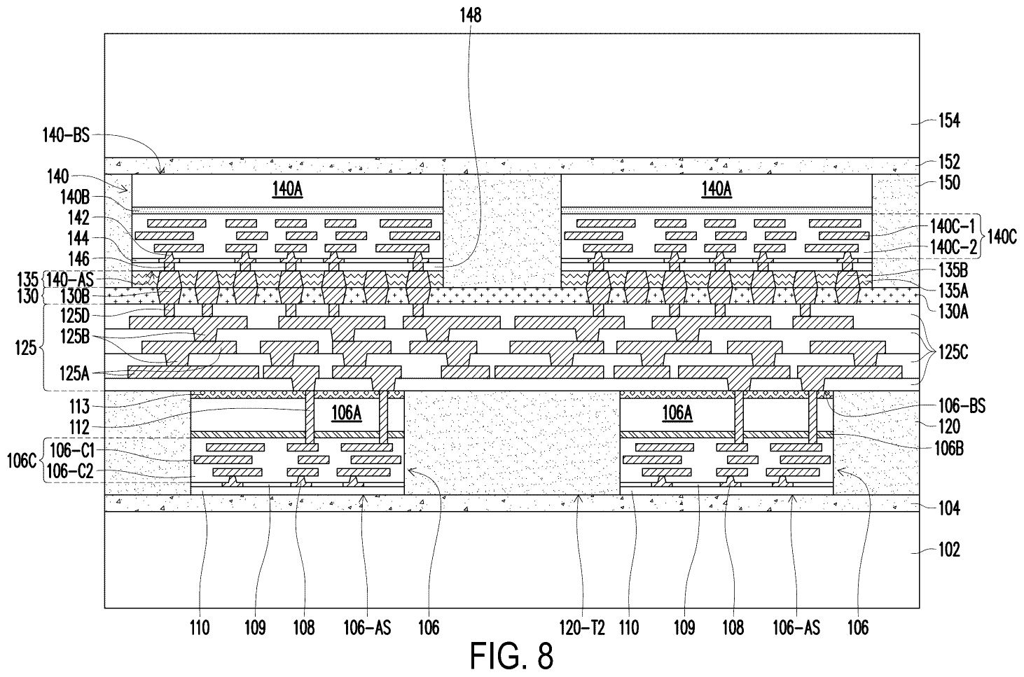

Referring to FIG. 8, in a subsequent step, a second carrier 154 is bonded to the backside surfaces 140-BS of the semiconductor dies 140 through a debond layer 152. For example, the debond layer 152 is located in between the insulating encapsulant 150 and the second carrier 154. The second carrier 154 may be a glass carrier or any suitable carrier for carrying a semiconductor wafer or a reconstituted wafer used for the method of fabricating the semiconductor package.

In some embodiments, the debond layer 152 may include a dielectric material layer made of a dielectric material including any suitable polymer-based dielectric material (such as benzocyclobutene (“BCB”), polybenzoxazole (“PBO”)). In an alternative embodiment, the debond layer 152 may include a dielectric material layer made of an epoxy-based thermal-release material, which loses its adhesive property when heated, such as a light-to-heat-conversion (LTHC) release coating film. In a further alternative embodiment, the debond layer 152 may include a dielectric material layer made of an ultra-violet (UV) glue, which loses its adhesive property when exposed to UV lights. In certain embodiments, the debond layer 152 may be dispensed as a liquid and cured, or may be a laminate film laminated onto the second carrier 154, or may be the like. The top surface of the debond layer 152, which is opposite to a bottom surface contacting the second carrier 154, may be levelled and may have a high degree of coplanarity. In certain embodiments, the debond layer 152 is, for example, a LTHC layer with good chemical resistance, and such layer enables room temperature de-bonding from the second carrier 154 by applying laser irradiation, however the disclosure is not limited thereto.

In an alternative embodiment, a buffer layer (not shown) may be coated on the debond layer 152, where the debond layer 152 is sandwiched between the buffer layer and the second carrier 154, and the top surface of the buffer layer may further provide a high degree of coplanarity. In some embodiments, the buffer layer may be a dielectric material layer. In some embodiments, the buffer layer may be a polymer layer which made of polyimide, polybenzoxazole (PBO), benzocyclobutene (BCB), or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

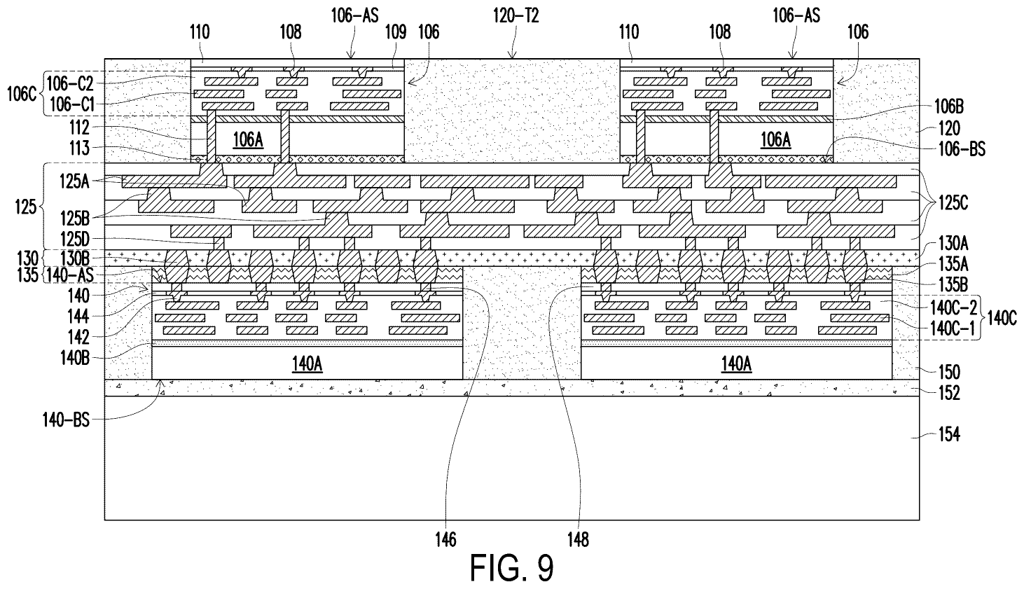

Referring to FIG. 9, after attaching the second carrier 154, the structure shown in FIG. 8 is flipped around, and the first carrier 102 is debonded to separate the semiconductor dies 106 from the first carrier 102. In some embodiments, the debonding process include projecting a light such as a laser light or an UV light on the debond layer 104, so that the first carrier 102 can be easily removed. As illustrated in FIG. 9, upon removing the first carrier 102, the active surface 106-AS of the semiconductor dies 106 are revealed. For example, the active surface 106-AS of the semiconductor dies 106 are coplanar and levelled with a surface 120-T2 of the insulating encapsulant 120.

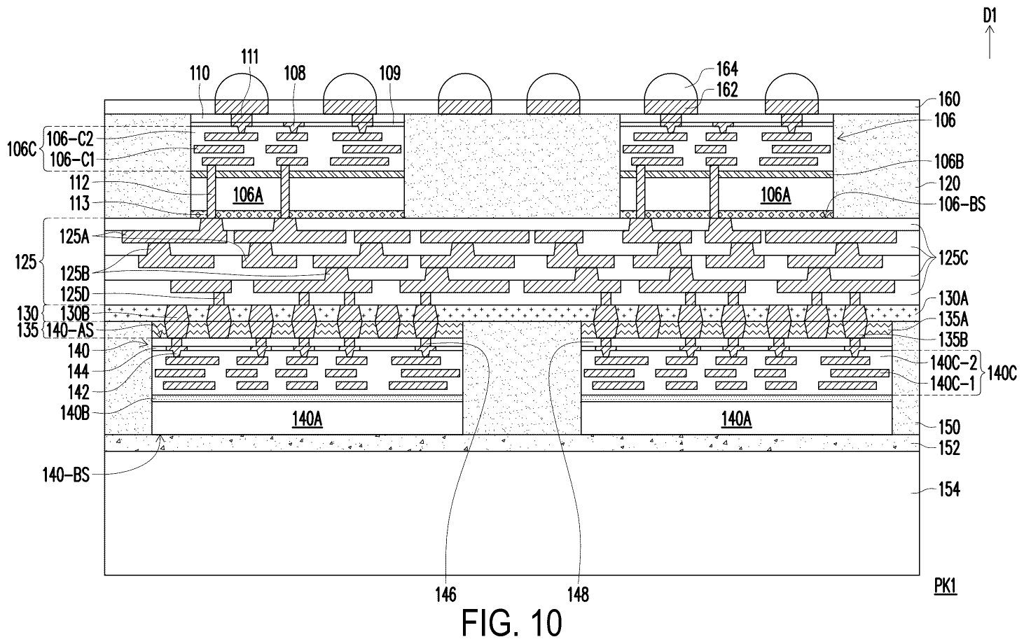

Referring to FIG. 10, in a subsequent step, the protection layer 110 of the semiconductor dies 106 are patterned to form openings revealing the conductive pads 108. Thereafter, conductive posts 111 are formed in the openings to be electrically connected to the conductive pads 108. In the exemplary embodiment, the conductive posts 111 are parts of the semiconductor dies 106. After forming the conductive posts 111 in the semiconductor dies 106, a plurality of conductive pads 162 is formed on the semiconductor dies 106, and a dielectric layer 160 is formed to surround the conductive pads 162. In some embodiments, the conductive pads 162 are disposed on and electrically connected to the conductive posts 111 of the semiconductor dies 106.

In some embodiments, the conductive pads 162 are for example, under-ball metallurgy (UBM) patterns used for ball mount. In some embodiments, the materials of the conductive pads 162 may include copper, nickel, titanium, tungsten, or alloys thereof or the like, and may be formed by an electroplating process, for example. The number of conductive pads 162 are not limited in this disclosure, and may be selected based on the design layout. In certain embodiments, the dielectric layer 160 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process.

After forming the conductive pads 162, a plurality of conductive terminals 164 is disposed on the conductive pads 162 and over the semiconductor dies 106. In some embodiments, the conductive terminals 164 may be disposed on the conductive pads 162 by a ball placement process or reflow process. In some embodiments, the conductive terminals 164 are, for example, solder balls or ball grid array (BGA) balls. In some embodiments, the conductive terminals 164 are connected to the semiconductor dies 106 through the conductive pads 162. The number of the conductive terminals 164 is not limited to the disclosure, and may be designated and selected based on the number of the conductive pads 162. After forming the conductive pads 162 and conductive terminals 164, multiple semiconductor packages PK1 including the above package components are formed on the same carrier substrate(s) and then singulated to form individual semiconductor package PK1.

In the semiconductor package PK1, a lateral dimension of the via portions of the conductive pads 142, a lateral dimension of the via portions of the conductive pads 108, and a lateral dimension of the bonding pads 135B increases along a first direction D1. Furthermore, a lateral dimension of the connection pads 130B and a lateral dimension of the conductive vias 125B decreases along the first direction D1. In the exemplary embodiment, the semiconductor dies 106 (second dies) are disposed on the semiconductor dies 140 (first dies) so that backside surfaces 106-BS of the semiconductor dies 106 are facing active surfaces 140-AS of the semiconductor dies 140. Furthermore, the redistribution layer 125 is located in between the semiconductor dies 106 and semiconductor dies 140 for providing interconnection therebetween. As such, in the semiconductor package PK1, the arrangement of the redistribution layer 125 in between the semiconductor dies (106, 140) allows for multiple data transferring path between die-to-die areas for signal communication. Therefore, with the additional transferring paths for signal communication, the semiconductor package PK1 can be used for super powerful data processing.

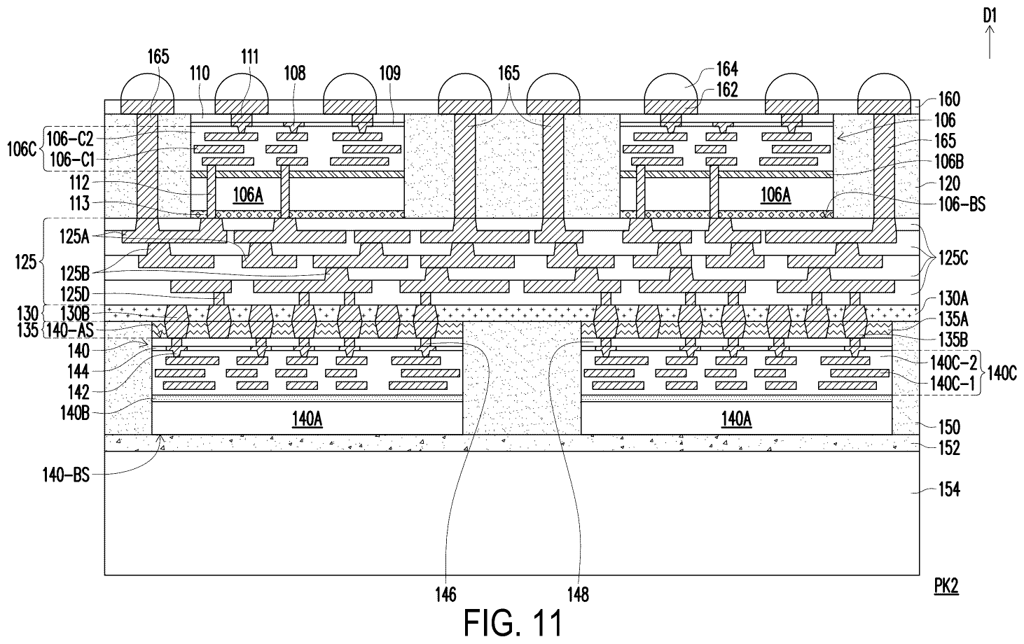

FIG. 11 is a schematic sectional view of a semiconductor package according to some exemplary embodiments of the present disclosure. The semiconductor package PK2 illustrated in FIG. 11 is similar to the semiconductor package PK1 illustrated in FIG. 10. Therefore, the same reference numerals are used to refer to the same or liked parts, and its detailed description will not be repeated herein. The difference between the embodiment of FIG. 11 and the embodiment of FIG. 10 is that the semiconductor package PK2 further includes a plurality of through insulating vias 165.

As illustrated in FIG. 11, the through insulator vias 165 are embedded in the insulating encapsulant 120 and surrounding the semiconductor dies 106. In some embodiments, the through insulator vias 165 are electrically connecting the redistribution layer 125 to the conductive terminals 164. The through insulator vias 165 may be formed by an electroplating or deposition process, and includes a metal material such as copper or copper alloys, or the like. In the semiconductor package PK2, since a redistribution layer 125 is arranged in between the semiconductor dies (106, 140), and through insulator vias 165 are further provided for vertical interconnection, this allows for multiple data transferring path between die-to-die areas for signal communication. Therefore, with the additional transferring paths for signal communication, the semiconductor package PK2 can be used for super powerful data processing.

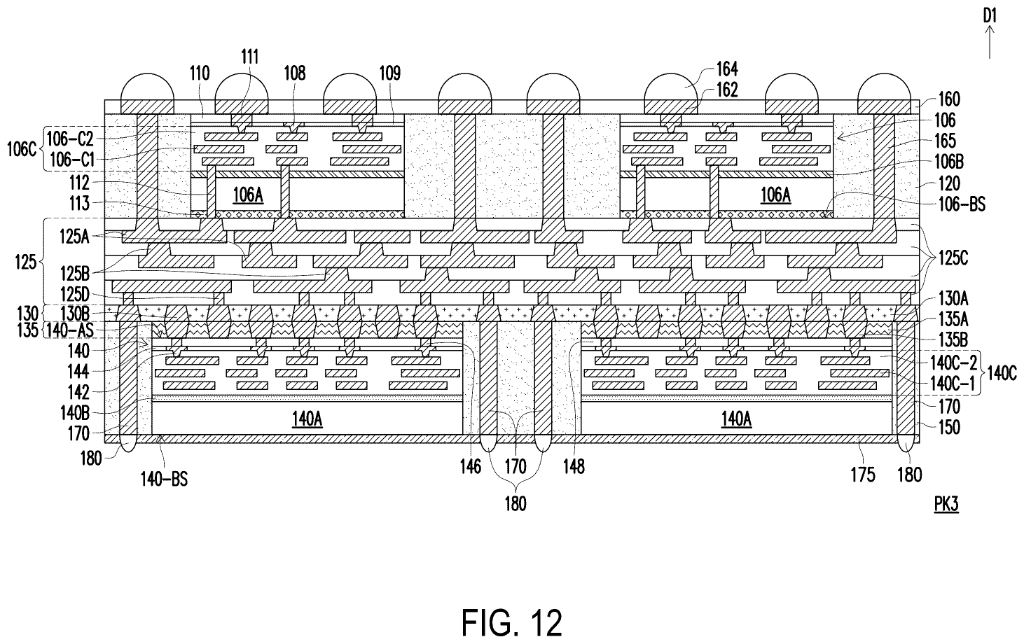

FIG. 12 is a schematic sectional view of a semiconductor package according to some other exemplary embodiments of the present disclosure. The semiconductor package PK3 illustrated in FIG. 12 is similar to the semiconductor package PK2 illustrated in FIG. 11. Therefore, the same reference numerals are used to refer to the same or liked parts, and its detailed description will not be repeated herein.

As illustrated in FIG. 12, besides forming the through insulator vias 165 in the insulating encapsulant 120, a plurality of through insulator vias 170 are further formed in the insulating encapsulant 150 to surround the semiconductor dies 140. In some embodiments, the second carrier 154 shown in the s emiconductor package PK2 of FIG. 11 is debonded from the package structure PK3 of FIG. 12. For example, the debond layer 152 and the second carrier 154 are separated from the semiconductor dies 140. In certain embodiments, the debond layer 152 (e.g., the LTHC release layer) may be irradiated by an UV laser such that the debond layer 152 is peeled from the second carrier 154. The debond layer 152 may be further removed or peeled off so that debond layer 152 is separated from the insulating encapsulant 150.

As further illustrated in FIG. 12, In some embodiment, a dielectric layer 175 is further formed on the insulating encapsulant 150, whereby the dielectric layer 175 is patterned to form a plurality of openings revealing the through insulator vias 170. In some embodiments, a plurality of conductive terminals 180 are, for example, reflowed to bond with the bottom surfaces of the through insulator vias 170. In certain embodiments, the through insulator vias 170 are electrically connecting the connection pads 130B of the connection layer 130 to the conductive terminals 180. After the conductive terminals 180 are formed, a semiconductor package PK3 having dual-side terminals is accomplished. The conductive terminals 180 allows for providing electrical connection of the semiconductor package PK3 to external components.

In the semiconductor package PK3, since a redistribution layer 125 is arranged in between the semiconductor dies (106, 140), and through insulator vias 165, 170 are further provided for vertical interconnection, this allows for multiple data transferring path between die-to-die areas for signal communication. Therefore, with the additional transferring paths for signal communication, the semiconductor package PK3 can be used for super powerful data processing.

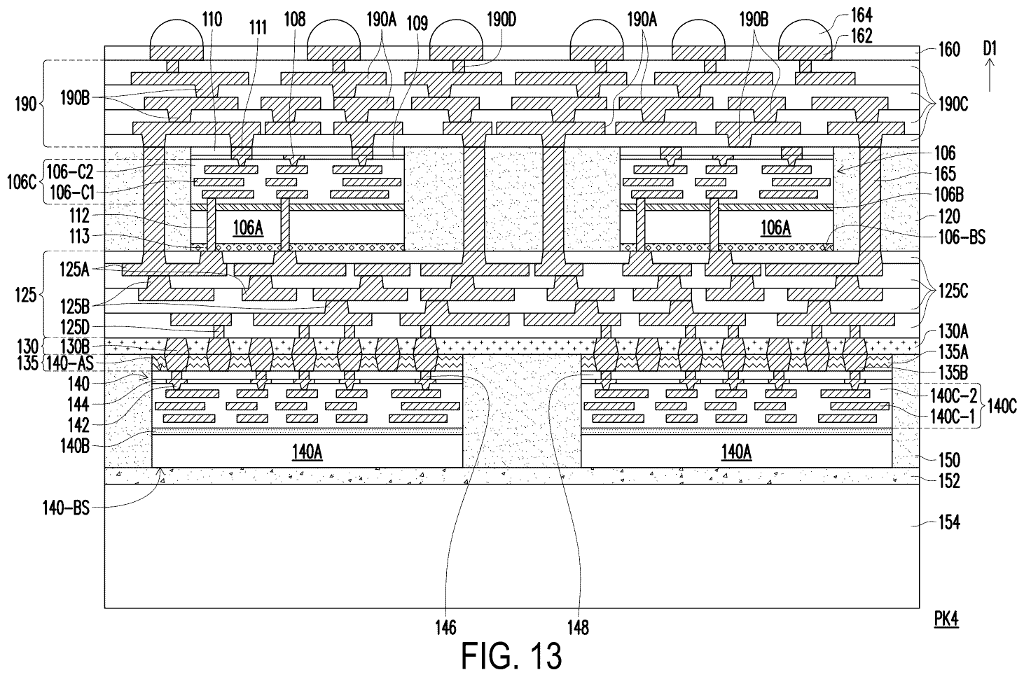

FIG. 13 is a schematic sectional view of a semiconductor package according to some other exemplary embodiments of the present disclosure. The semiconductor package PK4 illustrated in FIG. 13 is similar to the semiconductor package PK2 illustrated in FIG. 11. Therefore, the same reference numerals are used to refer to the same or liked parts, and its detailed description will not be repeated herein.

In the previous embodiments, the conductive pads 162 are shown to be directly formed on the active surfaces 106-AS of the semiconductor dies 106. However, the disclosure is not limited thereto. Referring to FIG. 13, a redistribution layer 190 is further formed on the active surfaces 106-AS of the semiconductor dies 106. For example, the redistribution layer 190 is formed in between the semiconductor dies 106 and the conductive pads 162. In certain embodiments, the redistribution layer 190 is electrically connecting the conductive posts 111 to the conductive pads 162, and electrically connecting the through insulator vias 165 to the conductive pads 162.

In the exemplary embodiment, the formation of the redistribution layer 190 includes forming a plurality of conductive lines 190A, a plurality of conductive vias 190B and a plurality of dielectric layers 190C alternately stacked. Although only three layers of the conductive lines 190A and the conductive vias 190B, and four layers of dielectric layers 190C are illustrated herein, however, the scope of the disclose is not limited by the embodiments of the disclosure. In other embodiments, the number of conductive lines 190A, conductive vias 190B and the dielectric layers 190C may be adjusted based on product requirement. In some embodiments, the redistribution layer 190 is electrically connected to semiconductor dies 106 and the through insulator vias 165 through the conductive lines 190A and the conductive vias 190B.

In some embodiments, a material of the dielectric layers 190C may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 190C may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive lines 190A and conductive vias 190B may be made of conductive materials formed by electroplating or deposition, such as aluminum, titanium, copper, nickel, tungsten, and/or alloys thereof, which may be patterned using a photolithography and etching process. In some embodiments, the conductive lines 190A and conductive vias 190B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the formation of the redistribution layer 190 further includes forming a plurality of connecting vias 190D. For example, the connecting vias 190D are electrically connecting a topmost conductive line 190A of the redistribution layer 190 to the conductive pads 162. In some embodiments, a material of the connecting vias 190D is similar to a material of the conductive vias 190B, thus its details will not be repeated herein. In some embodiments, the conductive vias 190B has slanted sidewalls, whereas the connecting vias 190D has linear sidewalls. Furthermore, a lateral dimension of the conductive vias 190B increase along the first direction D1. After forming the connecting vias 190D, a dielectric layer 160, conductive pads 162 and conductive terminals 164 may be formed on the redistribution layer 190, whereby the conductive pads 162 and conductive terminals 164 are electrically connected to the redistribution layer 190.

In the semiconductor package PK4, since a redistribution layer 125 is arranged in between the semiconductor dies (106, 140), another redistribution layer 190 is arranged above the semiconductors die 106, and through insulator vias 165 are further provided for vertical interconnection, this allows for multiple data transferring path between die-to-die areas for signal communication. Therefore, with the additional transferring paths for signal communication, the semiconductor package PK4 can be used for super powerful data processing.

In the above-mentioned embodiments, the semiconductor package at least includes a redistribution layer arranged in between first semiconductor dies and second semiconductor dies, which allows the transfer of die to die signals both horizontally and vertically. Such arrangement allows for multiple data transferring path between die-to-die areas for signal communication. Therefore, with the additional transferring paths for signal communication, the semiconductor package can be used for super powerful data processing.

In accordance with some embodiments of the present disclosure, a semiconductor package includes a plurality of first semiconductor dies, a first bonding layer, a redistribution layer, a plurality of second semiconductor dies and a plurality of conductive terminals. The first bonding layer is disposed on the first semiconductor dies, and includes a plurality of first bonding pads. The redistribution layer is disposed on and electrically connected to the first bonding pads. The second semiconductor dies are disposed on and electrically connected to the redistribution layer, wherein backside surfaces of the second semiconductor dies are facing active surfaces of the first semiconductor dies. The conductive terminals are disposed on and electrically connected to the second semiconductor dies.

In accordance with some other embodiments of the present disclosure, a semiconductor package includes a first semiconductor die, a second semiconductor die and a redistribution layer. The first semiconductor die includes a first semiconductor substrate and a first interconnection layer disposed on the first semiconductor substrate. The second semiconductor die includes a second semiconductor substrate, a second interconnection layer disposed on the second semiconductor substrate, and backside vias, extending from the second interconnection layer passing through the second semiconductor substrate and to a backside surface of the second semiconductor die. The redistribution layer is sandwiched between the first semiconductor die and the second semiconductor die, wherein the redistribution layer is physically and electrically connected to the backside vias of the second semiconductor die, and electrically connected to the first interconnection layer.

In accordance with yet another embodiment of the present disclosure, a method of fabricating a semiconductor package is described. The method includes: providing a plurality of second semiconductor dies; forming a redistribution layer, wherein the plurality of second semiconductor dies is disposed on and electrically connected to the redistribution layer; bonding a plurality of first semiconductor dies to the redistribution layer through a first bonding layer, wherein the first bonding layer is disposed on the plurality of first semiconductor dies and comprises a plurality of first bonding pads, and wherein after bonding the plurality of first semiconductor dies to the redistribution layer, the redistribution layer is electrically connected to the plurality of first bonding pads, and backside surfaces of the plurality of second semiconductor dies are facing active surfaces of the plurality of first semiconductor dies; and forming a plurality of conductive terminals disposed on and electrically connected to the plurality of second semiconductor dies.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a plurality of first semiconductor dies;
a first bonding layer disposed on the plurality of first semiconductor dies, and comprising a plurality of first bonding pads;
a redistribution layer disposed on and electrically connected to the plurality of first bonding pads;
a plurality of second semiconductor dies disposed on and electrically connected to the redistribution layer, wherein backside surfaces of the plurality of second semiconductor dies are facing active surfaces of the plurality of first semiconductor dies; and
a plurality of conductive terminals disposed on and electrically connected to the plurality of second semiconductor dies.

2. The semiconductor package according to claim 1, further comprising a connection layer electrically connected to the plurality of first bonding pads, wherein sidewalls of the connection layer are aligned with sidewalls of the redistribution layer.

3. The semiconductor package according to claim 1, wherein sidewalls of the first bonding layer are aligned with sidewalls of the plurality of first semiconductor dies.

4. The semiconductor package according to claim 1, wherein the redistribution layer comprises a plurality of conductive lines, a plurality of conductive vias and a plurality of dielectric layers alternately stacked, and a lateral dimension of the plurality of conductive vias decreases along a first direction, and wherein a lateral dimension of the plurality of first bonding pads increases along the first direction.

5. The semiconductor package according to claim 1, wherein each of the plurality of second semiconductor dies comprises a semiconductor substrate, an interconnection layer disposed on the substrate, and backside vias passing through the semiconductor substrate and electrically connecting the interconnection layer to the redistribution layer.

6. The semiconductor package according to claim 1, further comprising:
a first insulating encapsulant encapsulating the plurality of first semiconductor dies; and
a second insulating encapsulant encapsulating the plurality of second semiconductor dies, wherein the first insulating encapsulant is physically separated from the second insulating encapsulant.

7. The semiconductor package according to claim 6, further comprising a plurality of through insulating vias embedded in the second insulating encapsulant and electrically connecting the redistribution layer to the plurality of conductive terminals.

8. A semiconductor package, comprising:
a first semiconductor die, comprising:
a first semiconductor substrate; and
a first interconnection layer disposed on the first semiconductor substrate;
a second semiconductor die, comprising:
a second semiconductor substrate;
a second interconnection layer disposed on the second semiconductor substrate; and
backside vias, extending from the second interconnection layer passing through the second semiconductor substrate and to a backside surface of the second semiconductor die; and
a redistribution layer sandwiched between the first semiconductor die and the second semiconductor die, wherein the redistribution layer is physically and electrically connected to the backside vias of the second semiconductor die, and electrically connected to the first interconnection layer.

9. The semiconductor package according to claim 8, wherein the second semiconductor die further comprises a passivation layer contacting the redistribution layer and laterally surrounding the backside vias.

10. The semiconductor package according to claim 8, further comprising a first bonding layer disposed on the first semiconductor die, wherein the first bonding layer comprises a plurality of bonding pads electrically connected to the first interconnection layer of the first semiconductor die.

11. The semiconductor package according to claim 10, further comprising a connection layer disposed in between the first bonding layer and the redistribution layer, wherein the connection layer comprises a plurality of connection pads physically and electrically connected to the plurality of bonding pads and the redistribution layer.

12. The semiconductor package according to claim 11, wherein sidewalls of the first bonding layer are misaligned with sidewalls of the connection layer.

13. The semiconductor package according to claim 8, further comprising:
a plurality of conductive pads electrically connected to the second semiconductor die;
a dielectric layer surrounding the plurality of conductive pads; and
a plurality of conductive terminals disposed on the plurality of conductive pads.

14. The semiconductor package according to claim 8, further comprising:
a plurality of through insulating vias surrounding the first semiconductor die and the second semiconductor die.

15. The semiconductor package according to claim 8, further comprising:
a first insulating encapsulant surrounding the first semiconductor die; and
a second insulating encapsulant surrounding the second semiconductor die.

16. A method of fabricating a semiconductor package, comprising:
providing a plurality of second semiconductor dies;
forming a redistribution layer, wherein the plurality of second semiconductor dies is disposed on and electrically connected to the redistribution layer;
bonding a plurality of first semiconductor dies to the redistribution layer through a first bonding layer, wherein the first bonding layer is disposed on the plurality of first semiconductor dies and comprises a plurality of first bonding pads, and wherein after bonding the plurality of first semiconductor dies to the redistribution layer, the redistribution layer is electrically connected to the plurality of first bonding pads, and backside surfaces of the plurality of second semiconductor dies are facing active surfaces of the plurality of first semiconductor dies; and
forming a plurality of conductive terminals disposed on and electrically connected to the plurality of second semiconductor dies.

17. The method according to claim 16, wherein providing the plurality of second semiconductor dies comprises:
placing the plurality of second semiconductor dies on a first carrier;
thinning down a backside surface to reveal backside vias of the plurality of second semiconductor dies;
forming the redistribution layer on the backside surface of the plurality of second semiconductor dies; and
debonding the first carrier to forming the plurality of conductive terminals on an active surface of the plurality of second semiconductor dies.

18. The method according to claim 16, further comprises forming a connection layer electrically connected to the plurality of first bonding pads, wherein sidewalls of the connection layer are aligned with sidewalls of the redistribution layer.

19. The method according to claim 16, wherein forming the redistribution layer comprises forming a plurality of conductive lines and a plurality of conductive vias alternately stacked, wherein the redistribution layer is formed so that a lateral dimension of the plurality of conductive vias decreases along a first direction, and wherein the first bonding layer is formed so that a lateral dimension of the plurality of first bonding pads increases along the first direction.

20. The method according to claim 16, further comprises:
forming a first insulating encapsulant encapsulating the plurality of first semiconductor dies; and
forming a second insulating encapsulant encapsulating the plurality of second semiconductor dies, wherein the first insulating encapsulant is physically separated from the second insulating encapsulant.
